(19) United States
(12) Patent Application Publication
(10) Pub. No.: US 2025/0366033 A1
(43) Pub. Date: Nov. 27, 2025

(54) VERTICAL GATE-ALL-AROUND THIN FILM TRANSISTOR AND MANUFACTURING METHOD THEREOF

(71) Applicants: Beijing Superstring Academy of Memory Technology, Beijing (CN); INSTITUTE OF MICROELECTRONICS, CHINESE ACADEMY OF SCIENCES, Beijing (CN)

(72) Inventors: Gaobo XU, Beijing (CN); Zhiyu SONG, Beijing (CN); Gangping YAN, Beijing (CN); Shangbo YANG, Beijing (CN); Huaxiang YIN, Beijing (CN); Jun LUO, Beijing (CN)

(21) Appl. No.: 18/865,430

(22) PCT Filed: Dec. 29, 2022
(86) PCT No.: PCT/CN2022/143256

§ 371 Date: Nov. 13, 2024

(30) Foreign Application Priority Data
Nov. 24, 2022 (CN) 202211484334.1

(51) Int. Cl. H10D 30/67; H01L 23/31; H10D 30/01

(52) U.S. Cl. CPC H10D 30/6728; H01L 23/3171; H10D 30/0312; H10D 30/0318; H10D 30/6733; H10D 30/6735; H10D 30/6739; H10D 30/6757

(57) ABSTRACT

The present disclosure relates to a vertical gate-all-around thin film transistor and a method of manufacturing a vertical gate-all-around thin film transistor. The vertical gate-all-around thin film transistor includes a substrate; an isolation layer on the substrate; a source layer on the isolation layer; an annular thin film channel on the source layer; a drain layer on an upper part of the annular thin film channel; and a vertical surrounding gate filled on an inner side of the annular thin film channel and covering a sidewall of the annular thin film channel, wherein the substrate, the isolation layer, the source layer, the annular thin film channel, the drain layer, and the vertical surrounding gate are stacked sequentially from bottom to up.

### CROSS REFERENCE TO RELATED APPLICATION(S)

This application is a Section 371 National Stage Application of International Application No. PCT/CN2022/143256, filed on Dec. 29, 2022, which claims priority to Chinese Patent Application No. 202211484334.1, filed on Nov. 24, 2022 and entitled “VERTICAL GATE-ALL-AROUND THIN FILM TRANSISTOR AND MANUFACTURING METHOD THEREOF”, the entire content of which is incorporated herein in its entirety by reference.

### TECHNICAL FIELD

The present disclosure relates to a field of semiconductors, and in particular to a vertical gate-all-around thin film transistor and a method of manufacturing a vertical gate-all-around thin film transistor.

### BACKGROUND

The thin film transistor (TFT) is a type of a field effect transistor (FET), in which a semiconductor material of a channel is a deposited amorphous or polycrystalline thin film rather than a single crystal material. Amorphous Oxide-Semiconductor Thin Film Transistor (OSTFT) has great potential in fields of driver and memory for display panels as well as flexible circuits due to its low leakage current and simple low-temperature fabrication process. Indium gallium zinc oxide (InGaZnO, IGZO) has stable performance and is a commonly used material for oxide semiconductors.

### SUMMARY

The present disclosure provides a vertical gate-all-around thin film transistor, including: a substrate; an isolation layer on the substrate; a source layer on the isolation layer; an annular thin film channel on the source layer; a drain layer on an upper part of the annular thin film channel; and a vertical surrounding gate filled on an inner side of the annular thin film channel and covering a sidewall of the annular thin film channel, wherein the substrate, the isolation layer, the source layer, the annular thin film channel, the drain layer, and the vertical surrounding gate are stacked sequentially from bottom to up.

The present disclosure further provides a method of manufacturing a vertical gate-all-around thin film transistor, including: providing a substrate, wherein an isolation layer is provided on the substrate; growing a source layer on the isolation layer; growing a first sacrificial layer on the source layer and etching the first sacrificial layer into a first sacrificial block; growing a thin film channel layer outside the first sacrificial block, wherein the thin film channel layer wraps the first sacrificial block; growing a second sacrificial layer on the thin film channel layer; etching the second sacrificial layer and the thin film channel layer sequentially, wherein the second sacrificial layer is etched to form a second sacrificial block, a top part of the thin film channel layer is etched off to form an annular thin film channel, the first sacrificial block is located on an inner side of the annular thin film channel, and the second sacrificial block covers an outside of the annular thin film channel; growing a drain layer on an upper side of the annular thin film channel; removing the first sacrificial block and the second sacrificial block, so as to release the annular thin film channel; and growing a vertical surrounding gate at positions where the first sacrificial block and the second sacrificial block are originally located.

### BRIEF DESCRIPTION OF THE DRAWINGS

Various other advantages and benefits will become clear to those ordinary skilled in the art by reading the detailed description of preferred embodiments in the following. Accompanying drawings are only intended to illustrate preferred embodiments and are not considered a limitation of the present disclosure, and in the drawings:

FIG. 1 shows a schematic diagram of a grown isolation layer, a grown source layer, and a grown first sacrificial layer on a substrate in the present disclosure;

FIG. 2 shows a schematic diagram of an etched first sacrificial layer, a deposited thin film channel layer, and a deposited second sacrificial layer in the present disclosure;

FIG. 3 shows a schematic diagram of an etched thin film channel layer and an etched second sacrificial layer in the present disclosure;

FIG. 4 shows a schematic diagram of a deposited oxide isolation layer and a deposited drain layer in the present disclosure;

FIG. 5 shows a schematic diagram of a released annular thin film channel in the present disclosure;

FIG. 6 shows a top view of a device in the present disclosure; and

FIG. 7 shows a schematic diagram of a vertical gate-all-around thin film transistor in the present disclosure.

### DETAILED DESCRIPTION OF EMBODIMENTS

Hereinafter, embodiments of the present disclosure will be described with reference to accompanying drawings. However, it should be understood that these descriptions are illustrative and not intended to limit the scope of the present disclosure. Further, in the following, descriptions for known structures and technologies are omitted to avoid obscuring the concept of the present disclosure unnecessarily.

Various structures according to the embodiments of the present disclosure are shown in the accompanying drawings. However, they are not drawn to scale, and some features may be enlarged while some features may be omitted for sake of clarity. Shapes, relative sizes and positions of regions and layers shown in the drawings are only illustrative, and deviations may occur due to manufacture tolerances or technique limitations in practice. In addition, those skilled in the art may devise regions/layers of other different shapes, sizes, and relative positions as desired in practice.

In the context of the present disclosure, when a layer/element is recited as being “on” a further layer/element, the layer/element may be disposed directly on the further layer/element, or otherwise there may be an intervening layer/element interposed therebetween. Further, if a layer/element is “on” a further layer/element in an orientation, then the layer/element may be “under” the further layer/element when the orientation is turned.

Existing devices with horizontal and/or vertical channels are planar devices, in which the gate only covers one side of the channel, while due to the unevenness of the surface of the back channel on the other side, it is highly likely to cause carrier scattering and diffusion of impurities such as H, resulting in a deterioration of device performance. A method of forming IGZO vertical nanosheets through wet etching has a disadvantage of difficult control of over-etching amount, which cannot be used in extremely small devices and is not conducive to large-scale integration.

The present disclosure provides a vertical gate-all-around thin film transistor and a method of manufacturing a vertical gate-all-around thin film transistor. The gate-all-around transistor with a full enclosure structure may eliminate the instability caused by the back channel. For the gate-all-around transistor with the full enclosure structure, the method of using the spacer to form the channel layer does not require the wet process for nanosheets formation. Therefore, the gate-all-around transistor with the full enclosure structure has great potential for application in small-sized devices.

The present disclosure provides a method of manufacturing a vertical gate-all-around thin film transistor, including the following steps.

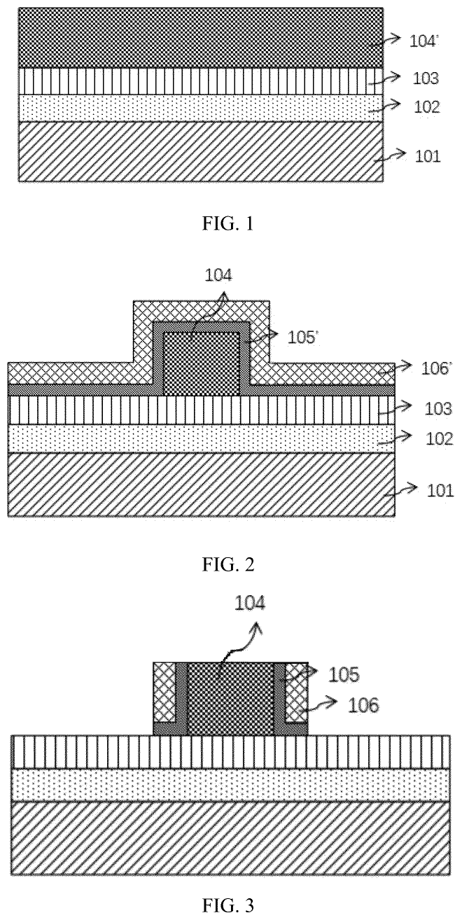

As shown in FIG. 1, a substrate 101 is provided, which is a part suitable for forming a semiconductor wafer of one or more IC devices. A bulk silicon substrate is used. A substrate isolation layer 102 is grown on the substrate 101 by deposition or epitaxial growth. A material of the substrate isolation layer may be selected from SiO₂ or Si₃N₄. A source layer 103 may be formed by depositing a source material on the substrate isolation layer 102 and patterning the source material through processes such as photolithography and etching. The source layer 103 may include TiN or TaN. A first sacrificial layer 104′ is formed on the source layer 103 by deposition. A material of the first sacrificial layer may be metal Mo.

The first sacrificial layer 104′ is etched into a first sacrificial block 104 through processes such as photolithography and etching. A shape of the first sacrificial block may be rectangular, cubic, or cylindrical, as shown in FIG. 2.

Next, as shown in FIG. 2, a thin film channel layer 105′ is deposited outside the first sacrificial block 104 through the deposition process. The thin film channel layer may include In₂O₃, ZnO, or IGZO with a thickness in a range of 10 nm to 20 nm. The thin film channel layer 105′ includes a horizontal part and a vertical part due to the conformal deposition. A second sacrificial layer 106′ is formed on the thin film channel layer 105′ by conformal deposition. A material of the second sacrificial layer may be metal Mo. Similarly, the second sacrificial layer 106′ includes a horizontal part and a vertical part.

As shown in FIG. 3, the thin film channel layer 105′ and the second sacrificial layer 106′ are etched through processes such as photolithography and etching. The thin film channel layer 105′ and the second sacrificial layer 106′ on the upper part of the first sacrificial block 104 are etched off, so that upper surfaces of the thin film channel layer 105′ and the second sacrificial layer 106′ are flush with an upper surface of the first sacrificial block 104. The horizontal part of the second sacrificial layer 106′ outside the first sacrificial block 104 and the corresponding horizontal part of the thin film channel layer 105′ below the horizontal part of the second sacrificial layer 106′ are etched off, so that the thin film channel layer 105′ is formed as an annular thin film channel 105. The annular thin film channel 105 has a protrusion at the bottom, so that the second sacrificial layer 106′ is formed as a second sacrificial block 106 covering the sidewall of the annular thin film channel 105.

At this point, the vertical part of the annular thin film channel 105 is substantially cylindrical, which may be a square or cylindrical cylinder. Generally, the shape of the annular thin film channel 105 depends on the shape of the first sacrificial block 104. The lower part of the annular thin film channel 105 is a horizontal part, namely a protrusion, which is used to increase electrical contact with the source layer 103. The first sacrificial block is located on an inner side of the annular thin film channel 105, and the second sacrificial block 106 covers the sidewall of the annular thin film channel 105.

Next, an oxide isolation layer 107 with a thickness in a range of 100 nm to 400 nm is grown on the device. A material of the oxide isolation layer is SiO₂ or a material with a low dielectric constant. Then, the CMP treatment is performed so that the upper surface of the oxide isolation layer 107 is flush with the upper surface of the vertical part of the annular thin film channel 105, that is, the upper surface of the annular thin film channel 105 is exposed. In this way, the oxide isolation layer 107 wraps the periphery of the second sacrificial block 106.

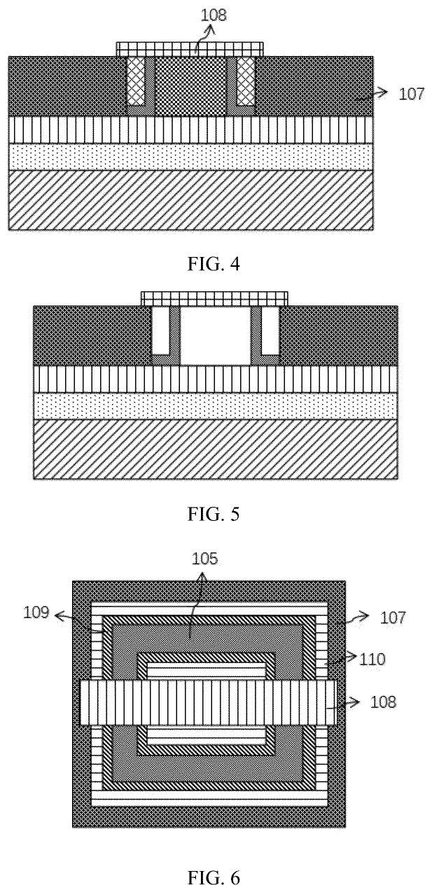

Then, a drain electrode layer is grown on the upper surface of the annular thin film channel 105, and patterned through photolithography and etching processes to form a drain layer 108, as shown in FIG. 4.

Next, the first sacrificial block 104 and the second sacrificial block 106 are removed, so as to release the annular thin film channel 105. In an embodiment, an existing wet process is used to isotropically etch the first sacrificial block 104 and the second sacrificial block 106, so as to release the annular thin film channel 105, thereby forming a nanosheet conductive channel, as shown in FIG. 5.

In the above, the formation and removal processes of the first sacrificial block 104 and the second sacrificial block 106 are the key to the process of the present disclosure, which may achieve the following effects: in an aspect, a metal spacer is used as the second sacrificial layer to protect the lower thin film during the etching process and release the channel; in another aspect, the semiconductor spacer is used as the annular thin film channel 105, the first sacrificial block 104 and the second sacrificial block 106 are etched off, so that the sheet-like or columnar semiconductor spacer channel is placed between the upper source/drain metal and the lower source/drain metal, and then filling the gate dielectric and the gate metal to achieve the gate-all-around structure (which is similar to the stack nanosheet gate-all-around transistor (GAA FET) of silicon devices); in yet another aspect, the annular thin film channel 105 of the present disclosure is vertical, and the manufacturing process of the channel does not require epitaxy, using PVD, CVD, or ALD is sufficient.

Next, a vertical surrounding gate is deposited and filled in the space where the first sacrificial block 104 and the second sacrificial block 106 are originally located (meanwhile, the vertical surrounding gate is also deposited on the upper surface of the drain layer 108). The vertical surrounding gate includes a gate dielectric layer 109 and a gate metal layer 110. The gate dielectric layer 109 is deposited, and then the gate metal layer 110 is deposited, so that the vertical surrounding gate is formed for the annular thin film channel 105, that is, the gate is distributed inside and outside the annular thin film channel 105, as well as on the upper part of the drain layer 108, which may effectively control the carriers for the annular thin film channel 105 in a surrounding manner. For ease of understanding, FIG. 6 provides a top view of the device, which clearly shows the spatial distribution of the vertical surrounding gate, the annular thin film channel 105, and the drain layer 108.

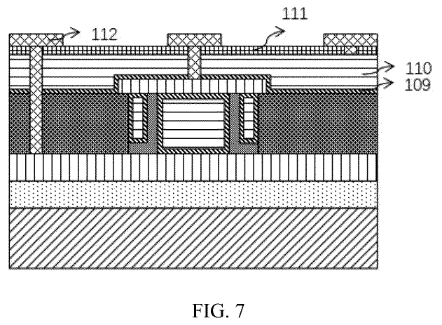

Then, a passivation film 111 is formed by performing the ILD-1 dielectric deposition at the top. The vertical gate-all-around thin film transistor as shown in FIG. 7 is formed by performing contact hole photolithography and etching, depositing the hole silicide 112, leading out the contact electrode, followed by completing multiple interconnection processes in back end of line and passivation protection processes. It should be noted that before the ILD-1 dielectric deposition, the gate metal layer 110 covering the drain layer 108 may be removed (or along with the removal of the gate dielectric layer 109) to release the space and make the device more miniaturized.

Compared with the related art, the present disclosure achieves the following technical effects.
(1) The present disclosure proposes a vertical gate-all-around oxide thin film transistor and a manufacturing method thereof based on growing the channel layer on the sidewall of the step of the sacrificial layer, which simplifies the manufacturing process of the vertical device. The vertical gate-all-around device may improve the control ability of the gate on the channel, suppress the short channel effect, reduce the leakage current, improve various performance indicators of the device, and reduce the cell area.
(2) The spacer made of metal or other materials is used as the second sacrificial layer to protect the lower thin film during the etching process and release the channel.
(3) The semiconductor spacer is used as the channel in the vertical direction. By etching off the first sacrificial layer and the second sacrificial layer, the sheet-like or columnar semiconductor spacer channel is placed between the lower source/drain metal and the upper source/drain metal, and then filling the gate dielectric and the gate metal to achieve the gate-all-around structure.
(4) Compared with an existing stack nanosheet gate-all-around transistor (GAA FET), the square channel of the present disclosure is vertical, and the manufacturing process of the channel does not require epitaxy, using PVD, CVD, or ALD is sufficient.
(5) The method using a plurality of sacrificial layers may reduce the requirement for photolithography linewidth, and improve the process consistency and margin in extremely small size applications.

Embodiments of the present disclosure have been described above. However, these embodiments are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

1. A vertical gate-all-around thin film transistor, comprising:
a substrate;
an isolation layer on the substrate;
a source layer on the isolation layer;
an annular thin film channel on the source layer;
a drain layer on an upper part of the annular thin film channel; and
a vertical surrounding gate filled on an inner side of the annular thin film channel and covering a sidewall of the annular thin film channel,
wherein the substrate, the isolation layer, the source layer, the annular thin film channel, the drain layer, and the vertical surrounding gate are stacked sequentially from bottom to up.

2. The vertical gate-all-around thin film transistor according to claim 1, wherein the annular thin film channel is in an annular shape and has a protrusion at a bottom of the annular thin film channel.

3. The vertical gate-all-around thin film transistor according to claim 2, wherein the vertical surrounding gate comprises a stack of a gate dielectric layer and a gate metal layer.

4. The vertical gate-all-around thin film transistor according to claim 3, wherein the gate metal layer comprises TiN or TaN; and/or each of the source layer and the drain layer comprises TiN or TaN.

5. The vertical gate-all-around thin film transistor according to claim 1, wherein a material of the isolation layer is selected from SiO₂ or Si₃N₄.

6. The vertical gate-all-around thin film transistor according to claim 1, wherein a passivation layer is provided on an upper part of the drain layer, and a material of the passivation layer is Al₂O₃, HfO₂ or SiO₂.

7. The vertical gate-all-around thin film transistor according to claim 6, wherein a stack of a gate dielectric layer and a gate metal layer is provided between the drain layer and the passivation layer.

8. A method of manufacturing a vertical gate-all-around thin film transistor, comprising:
providing a substrate, wherein an isolation layer is provided on the substrate;
growing a source layer on the isolation layer;
growing a first sacrificial layer on the source layer and etching the first sacrificial layer into a first sacrificial block;
growing a thin film channel layer outside the first sacrificial block, wherein the thin film channel layer wraps the first sacrificial block;
growing a second sacrificial layer on the thin film channel layer;
etching the second sacrificial layer and the thin film channel layer sequentially, wherein the second sacrificial layer is etched to form a second sacrificial block, a top part of the thin film channel layer is etched off to form an annular thin film channel, the first sacrificial block is located on an inner side of the annular thin film channel, and the second sacrificial block covers an outside of the annular thin film channel;
growing a drain layer on an upper side of the annular thin film channel;
removing the first sacrificial block and the second sacrificial block, so as to release the annular thin film channel; and
growing a vertical surrounding gate at positions where the first sacrificial block and the second sacrificial block are originally located.

9. The method according to claim 8, wherein the annular thin film channel is in an annular shape and has a protrusion at a bottom of the annular thin film channel.

10. The method according to claim 8, wherein the vertical surrounding gate comprises a stack of a gate dielectric layer and a gate metal layer.
